(19) United States
(12) Patent Application Publication
(10) Pub. No.: US 2026/0324072 A1
(43) Pub. Date: Oct. 15, 2026

(54) ARRAY SUBSTRATE AND MANUFACTURING METHOD THEREOF, DISPLAY PANEL, AND DISPLAY DEVICE

(71) Applicants: BEIJING BOE DISPLAY TECHNOLOGY CO., LTD., Beijing (CN); BOE TECHNOLOGY GROUP CO., LTD., Beijing (CN)

(72) Inventors: Liyan XU, Beijing (CN); Dan XIE, Beijing (CN); Xiaoyi ZHENG, Beijing (CN); Enqiang ZHENG, Beijing (CN); Zhixiao YAO, Beijing (CN); Jiarong LIU, Beijing (CN); Kangkang GAO, Beijing (CN); Chenchen WU, Beijing (CN); Bairu LU, Beijing (CN); Yanna ZHAO, Beijing (CN); Jie ZHANG, Beijing (CN); Huaizong CHENG, Beijing (CN)

(73) Assignees: BEIJING BOE DISPLAY TECHNOLOGY CO., LTD., Beijing (CN); BOE TECHNOLOGY GROUP CO., LTD., Beijing (CN)

(21) Appl. No.: 18/847,939

(22) PCT Filed: Nov. 13, 2023
(86) PCT No.: PCT/CN2023/131199

§ 371 Date: Sep. 17, 2024

(51) Int. Cl. H10D 86/40; G02F 1/1345; H10D 86/60

(52) U.S. Cl. CPC H10D 86/441; G02F 1/1345; H10D 86/451; H10D 86/60

(57) ABSTRACT

Provided are an array substrate and a manufacturing method thereof, a display panel and a display device. The array substrate includes: a base substrate including a binding area including a first and second binding area; a first group of pads at the first bonding area; a second group of pads at the second binding area; a signal line; a planarization layer having a groove, orthographic projection of the binding area on the base substrate being within that of the groove; an insulating layer; and connectors, each connector being connected to a corresponding pad in the first group of pads via a corresponding first connection line, and connected to a corresponding pad in the second group of pads via a corresponding second connection line. Orthographic projections of each connector on the base substrate overlaps with that of the signal line and does not overlap with that of the groove.

### CROSS-REFERENCE TO RELATED APPLICATIONS

The present application is a U.S. National Stage Application under 35 U.S.C. 371 of International Patent Application No. PCT/CN2023/131199, filed on Nov. 13, 2023, the disclosure of which is incorporated by reference herein in its entirety.

### TECHNICAL FIELD

The present disclosure relates to an array substrate and a manufacturing method thereof, a display panel, and a display device.

### BACKGROUND

The TDDI (Touch and Display Driver Integration) display product integrates a touch chip and a display chip into a single chip, which is helpful to reduce the thickness of the display product, improve the brightness of the display product, and contribute to the design of a narrow border of the display product.

With the development of the display technology, people have higher and higher requirements for the display quality of the display product such as a TDDI product.

### SUMMARY

According to a first aspect of the embodiment of the present disclosure, provided is an array substrate. The array substrate comprises: a base substrate comprising a display area and a binding area located on one side of the display area, wherein the binding area comprises a first binding area and a second binding area located on one side of the first binding area away from the display area; a first group of pads located at the first binding area; a second group of pads located at the second binding area; a signal line located on one side of the base substrate; a planarization layer located on one side of the signal line away from the base substrate, wherein the planarization layer has a groove, and an orthographic projection of the binding area on the base substrate is located within an orthographic projection of the groove on the base substrate; an insulating layer located on one side of the planarization layer away from the base substrate; and a plurality of connectors located on one side of the insulating layer away from the base substrate, wherein each of the plurality of connectors is connected to a corresponding pad in the first group of pads via a corresponding first connection line respectively, and connected to a corresponding pad in the second group of pads via a corresponding second connection line respectively, wherein an orthographic projection of each of the plurality of connectors on the base substrate overlaps with an orthographic projection of the signal line on the base substrate, and does not overlap with the orthographic projection of the groove on the base substrate.

In some embodiments, the orthogonal projection of the signal line on the base substrate overlaps with the orthogonal projection of the groove on the base substrate.

According to second aspect of the embodiments of the present disclosure, provided is an array substrate. The array substrate comprises: a base substrate comprising a display area and a binding area located on one side of the display area, wherein the binding area comprises a first binding area and a second binding area located on one side of the first binding area away from the display area; a first group of pads located at the first binding area; a second group of pads located at the second binding area; a signal line located on one side of the base substrate; a planarization layer located on one side of the signal line away from the base substrate, wherein the planarization layer has a groove, and an orthographic projection of the binding area on the base substrate is located within an orthographic projection of the groove on the base substrate; an insulating layer located on one side of the planarization layer away from the base substrate; and a plurality of connectors located on one side of the insulating layer away from the base substrate, wherein each of the plurality of connectors is connected to a corresponding pad in the first group of pads via a corresponding first connection line respectively, and connected to a corresponding pad in the second group of pads via a corresponding second connection line respectively, wherein an overlapping portion of orthogonal projections of the signal line and the groove on the base substrate does not overlap with an orthogonal projection of each of the plurality of connectors on the base substrate.

In some embodiments, the plurality of connectors comprises a first connector configured to be applied a low-level voltage signal in at least one stage.

In some embodiments, the plurality of connectors further comprises a second connector configured to be applied a common voltage signal in the at least one stage.

According to third aspect of the embodiments of the present disclosure, provided is an array substrate. The array substrate comprises: a base substrate comprising a display area and a binding area located on one side of the display area, wherein the binding area comprises a first binding area and a second binding area located on one side of the first binding area away from the display area; a first group of pads located at the first binding area; a second group of pads located at the second binding area; a signal line located on one side of the base substrate; a planarization layer located on one side of the signal line away from the base substrate, wherein the planarization layer has a groove, and an orthographic projection of the binding area on the base substrate is located within an orthographic projection of the groove on the base substrate; an insulating layer located on one side of the planarization layer away from the base substrate; and a first connector located on one side of the insulating layer away from the base substrate and configured to be applied a low-level voltage signal in at least one stage, wherein the first connector is connected to a corresponding pad in the first group of pads via a corresponding first connection line, and connected to a corresponding pad in the second group of pads via a corresponding second connection line, wherein an orthographic projection of the first connector on the base substrate overlaps with an orthographic projection of the signal line on the base substrate, and does not overlap with the orthographic projection of the groove on the base substrate.

In some embodiments, the orthogonal projection of the signal line on the base substrate overlaps with the orthogonal projection of the groove on the base substrate.

According to fourth aspect of the embodiments of the present disclosure, provided is an array substrate. The array substrate comprises: a base substrate comprising a display area and a binding area located on one side of the display area, wherein the binding area comprises a first binding area and a second binding area located on one side of the first binding area away from the display area; a first group of pads located at the first binding area; a second group of pads located at the second binding area; a signal line located on one side of the base substrate; a planarization layer located on one side of the signal line away from the base substrate, wherein the planarization layer has a groove, and an orthographic projection of the binding area on the base substrate is located within an orthographic projection of the groove on the base substrate; an insulating layer located on one side of the planarization layer away from the base substrate; and a first connector located on one side of the insulating layer away from the base substrate and configured to be applied a low-level voltage signal in at least one stage, wherein the first connector is connected to a corresponding pad in the first group of pads via a corresponding first connection line, and connected to a corresponding pad in the second group of pads via a corresponding second connection line, wherein an overlapping portion of orthographic projections of the signal line and the groove on the base substrate does not overlap with an orthographic projection of the first connector on the base substrate.

In some embodiments, the array substrate further comprises: a second connector located on one side of the insulating layer away from the base substrate and configured to be applied a common voltage signal in the at least one stage, wherein the second connector is connected to a corresponding pad in the first group of pads via a corresponding first connection line, and connected to a corresponding pad in the second group of pads via a corresponding second connection line, wherein an orthographic projection of the second connector on the base substrate overlaps with the orthographic projection of the signal line on the base substrate, and does not overlap with the orthographic projection of the groove on the base substrate.

In some embodiments, the array substrate further comprises: a second connector located on one side of the insulating layer away from the base substrate and configured to be applied a common voltage signal in the at least one stage, wherein the second connector is connected to a corresponding pad in the first group of pads via a corresponding first connection line, and connected to a corresponding pad in the second group of pads via a corresponding second connection line, wherein an overlapping portion of orthographic projections of the signal line and the groove on the base substrate does not overlap with an orthographic projection of the second connector on the base substrate.

In some embodiments, the array substrate further comprises: a touch signal line located at the display area; and a switch, wherein a gate of the switch is connected to the first connector via a first pad in the first group of pads, a first electrode of the switch is connected to the second connector via a second pad in the first group of pads, and a second electrode of the switch is connected to the touch signal line.

In some embodiments, an orthographic projection of the first connector on the base substrate is located between an orthographic projection of the second connector on the base substrate and the binding area.

In some embodiments, the at least one stage is a stage during an on-going reliability test.

In some embodiments, the array substrate further comprises: a gate drive circuit configured to provide a gate driving signal to a sub-pixel located at the display area, wherein the signal line is configured to provide a signal to the gate drive circuit.

In some embodiments, the array substrate further comprises: a touch electrode multiplexed as a common electrode.

some embodiments, the first binding area is an integrated circuit binding area; and the second binding area is a circuit board binding area.

In some embodiments, at least one connector is located in a same layer as one of a pixel electrode and a common electrode in the array substrate.

In some embodiments, a material of at least one connector comprises a transparent conductive oxide.

According to a fifth aspect of the embodiment of the present disclosure, a display panel is provided. The display panel comprises: the array substrate according to any of the above embodiments; a color filter substrate; and a liquid crystal layer located between the array substrate and the color filter substrate.

According to a sixth aspect of the embodiment of the present disclosure, a display device is provided. The display device comprises: the display panel according to any of the above embodiments.

According to a seventh aspect of the embodiment of the present disclosure, a manufacturing method of an array substrate is provided. The manufacturing method comprises: providing a base substrate, wherein the base substrate comprises a display area and a binding area located on one side of the display area, and the binding area comprises a first binding area and a second binding area located on one side of the first binding area away from the display area; forming a first group of pads located at the first binding area; forming a second group of pads located at the second binding area; forming a signal line on one side of the substrate; forming a planarization layer on one side of the signal line away from the base substrate, wherein the planarization layer has a groove, and an orthographic projection of the binding area on the base substrate is located within an orthographic projection of the groove on the base substrate; forming an insulating layer on one side of the planarization layer away from the substrate; and forming a plurality of connectors on one side of the insulating layer away from the base substrate, wherein each of the plurality of connectors is connected to a corresponding pad in the first group of pads via a corresponding first connection line respectively, and connected to a corresponding pad in the second group of pads via a corresponding second connection line respectively, wherein an orthographic projection of each of the plurality of connectors on the base substrate overlaps with an orthographic projection of the signal line on the base substrate, and does not overlap the orthographic projection of the groove on the base substrate.

### BRIEF DESCRIPTION OF THE DRAWINGS

The accompanying drawings which constitute part of this specification, describe the embodiments of the present disclosure, and together with this specification, serve to explain the principles of the present disclosure.

The present disclosure may be more explicitly understood from the following detailed description with reference to the accompanying drawings, in which:

FIG. 1 is a schematic structural view showing an array substrate according to some embodiments of the present disclosure;

FIG. 2 is a schematic structural view showing a portion of an array substrate corresponding to a display area according to some embodiments of the present disclosure;

FIG. 3 is a partial schematic structure view showing an array substrate according to some embodiments of the present disclosure;

FIG. 4 is a schematic cross-sectional view taken along A-A′ shown in FIG. 3;

FIG. 5 is a schematic cross-sectional view taken along B-B′ shown in FIG. 3;

FIG. 6 is a schematic cross-sectional view taken along C-C′ shown in FIG. 3;

FIG. 7 is a schematic cross-sectional view taken along D-D′ shown in FIG. 3;

FIG. 8A is a partial schematic view showing an array substrate in the related art;

FIG. 8B is a partial schematic view showing an array substrate according to some embodiments of the present disclosure;

FIG. 9 is a schematic structural view showing a display panel according to some embodiments of the present disclosure;

FIG. 10 is a flowchart showing a manufacturing method of an array substrate according to some embodiments of the present disclosure;

FIG. 11 is a flowchart showing a manufacturing method of an array substrate according to other embodiments of the present disclosure.

It should be appreciated that, the same or similar reference numerals refer to the same or similar components.

### DETAILED DESCRIPTION

Various exemplary embodiments of the present disclosure will now be described in detail with reference to the accompanying drawings. The following description of the exemplary embodiments is merely illustrative and is in no way intended as a limitation to the present disclosure, its application or use. The present disclosure may be implemented in many different forms, which are not limited to the embodiments described herein. These embodiments are provided to make the present disclosure thorough and complete, and fully convey the scope of the present disclosure to those skilled in the art. It should be noticed that: relative arrangement of components and steps, material composition, numerical expressions, and numerical values set forth in these embodiments, unless specifically stated otherwise, should be explained as merely illustrative, and not as a limitation.

The use of the terms “first”, “second” and similar words in the present disclosure do not denote any order, quantity, or importance, but are merely used to distinguish between different parts. A word such as “comprise”, “have” or variants thereof means that the element before the word covers the element(s) listed after the word without excluding the possibility of also covering other elements. The terms “up”, “down”, or the like are used only to represent a relative positional relationship, and the relative positional relationship may be changed correspondingly if the absolute position of the described object changes.

In the present disclosure, when it is described that a specific component is disposed between a first component and a second component, there may be an intervening component between the specific component and the first component or between the specific component and the second component. When it is described that a specific part is connected to other parts, the specific part may be directly connected to the other parts without an intervening part, or not directly connected to the other parts with an intervening part.

Unless otherwise defined, all terms (including technical and scientific terms) used herein have the same meanings as the meanings commonly understood by one of ordinary skill in the art to which the present disclosure belongs. It should also be understood that terms as defined in general dictionaries, unless explicitly defined herein, should be interpreted as having meanings that are consistent with their meanings in the context of the relevant art, and not to be interpreted in an idealized or extremely formalized sense.

Techniques, methods, and apparatus known to those of ordinary skill in the relevant art may not be discussed in detail, but where appropriate, these techniques, methods, and apparatuses should be considered as part of this specification.

The inventors have noticed that, some display products (for example, small-size TDDI products) are subject to poor display of blur during an on-going reliability test process.

In order to solve this problem, the inventors have found that, poor display occurs in the vicinity of a binding area of the integrated circuit (IC). Through further analysis, it has been found that, poor display occurs at a boundary position of a groove of a planarization layer. After further analysis by FIB (Focused Ion Beam) technology, it has been found that, the boundary of a groove of the planarization layer is crossed by a connector for transmitting a signal, and the signal line under the connector crossed by the boundary of the groove is corroded, which results in an abnormal signal and leads to poor display. In a case where the signal line is used for transmitting a signal to the gate drive circuit (GOA), the signal line being corroded results in abnormal signal output of the gate drive circuit and leads to poor blur display.

After further analysis, the inventors have found that, the insulation layer between the connector and the signal line tends to be damaged under electrostatic discharge (ESD) or high-temperature and high-humidity environment. For example, ESD tends to gather at a climbing position of the groove to break through the insulation layer. Since there is no planarization layer between a portion of the signal line crossed with the groove of the planarization layer and the connector, the thickness of the insulation layer therebetween is small, and the insulation layer is more easily to be broken down. In a case where a voltage signal is applied to the connector, there is a voltage difference between the connector and the signal line, which is prone to an electrochemical corrosion phenomenon and leads to corrosion of the signal line.

In view showing this, the embodiments of the present disclosure provide the following technical solutions, which can at least reduce the corrosion of the signal line to alleviate the problem of poor display.

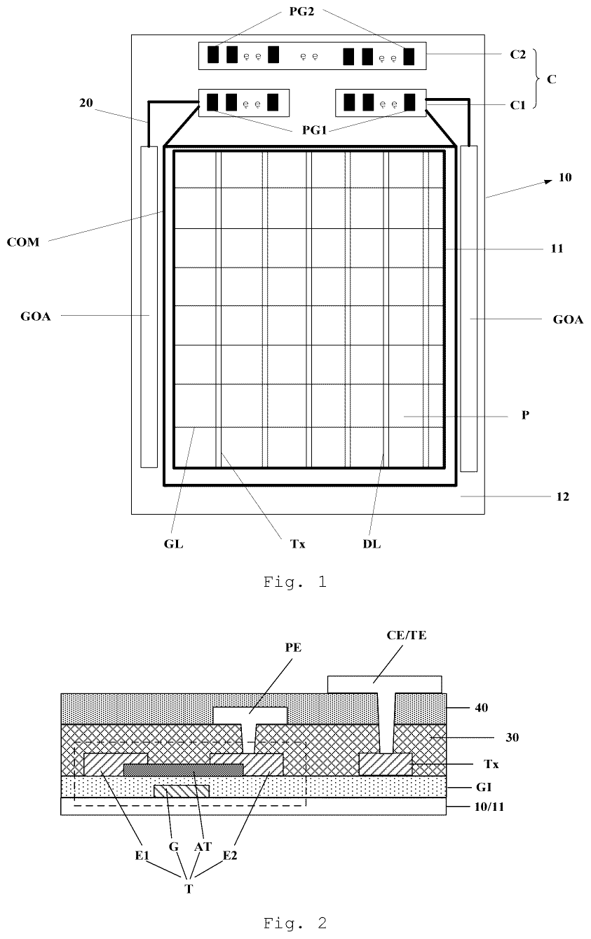

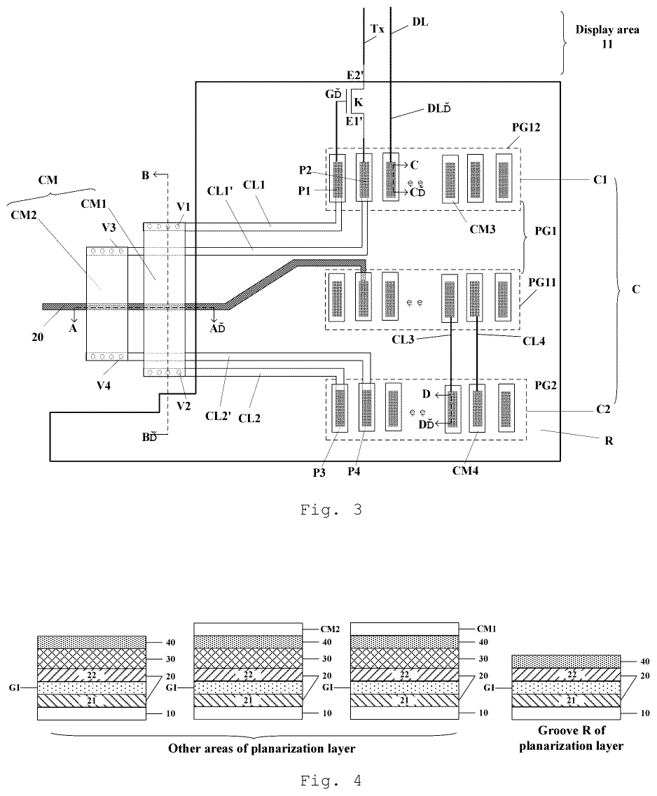

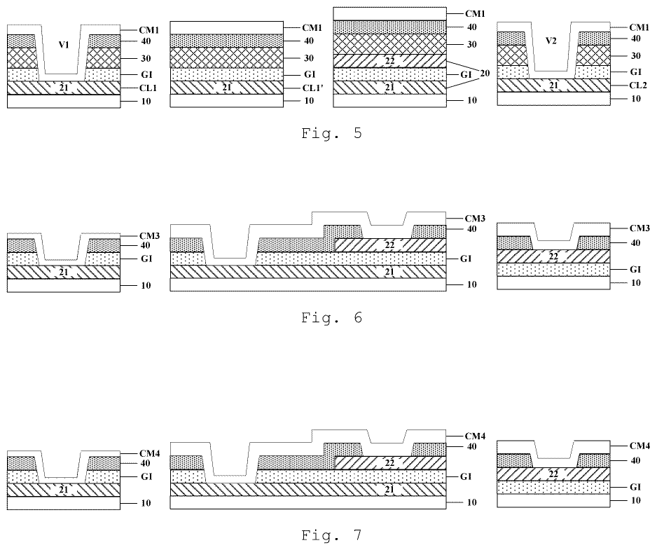

FIG. 1 is a schematic structural view showing an array substrate according to some embodiments of the present disclosure. FIG. 2 is a schematic structural view showing a portion of an array substrate corresponding to a display area according to some embodiments of the present disclosure. FIG. 3 is a partial schematic view showing an array substrate according to some embodiments of the present disclosure. FIG. 4 is a schematic cross-sectional view taken along A-A′ shown in FIG. 3.

Next, an array substrate according to some embodiments of the present disclosure will be introduced in conjunction with FIGS. 1 to 4.

As shown in FIGS. 1 to 4, the array substrate comprises a base substrate 10, a first group of pads PG1, a second group of pads PG2, a signal line 20, a planarization layer 30 and an insulating layer 40.

First, the base substrate 10, the first group of pads PG1 and the second group of pads PG2 will be introduced in conjunction with FIGS. 1 and 3.

Referring to FIG. 1, the base substrate 10 comprises a display area 11 and a peripheral area 12. The peripheral area 12 comprises a binding area C located on one side of the display area 11. It should be understood that, the peripheral area 12 may also comprise other peripheral areas, for example, a peripheral area opposite to the binding area C (i.e., the peripheral area located below the display area 11) and a peripheral area adjacent to the binding area C (i.e., the peripheral areas located on the left and right sides of the display area 11). For example, the base substrate 10 is a glass substrate. It is to be noted that, although the display area 11 shown in FIG. 1 is rectangular, this is not restrictive. In some embodiments, the corner of the display area 11 may have a radian, for example, a circular arc. Accordingly, the corner of the peripheral area 12 may also have a radian.

Referring to FIGS. 1 and 3, the binding area C comprises a first binding area C1, and a second binding area C2 located on one side of the first binding area C1 away from the display area 11. In some embodiments, the first binding area Cl is an integrated circuit (IC) binding area, which may be provided with an integrated circuit, such as a TDDI circuit. The TDDI circuit can realize display and touch drive. In some embodiments, the second binding area C2 is a circuit board binding area, which may be provided with a circuit board, for example, a flexible printed circuit board (FPC). The circuit board may be connected to an external control device.

The first group of pads PG1 is located at the first binding area C1, and the second group of pads PG2 is located at the second binding area C2. For example, the integrated circuit may be bound with the first group of pads PG1 to transmit a signal through the first group of pads PG1. The circuit board may be bound with the second group of pads PG2. In some embodiments, the first group of pads PG1 and the second group of pads PG2 may each comprise a plurality of pads. In some embodiments, one or more pads of the first group of pads PG1 may be connected to one or more pads of the second group of pads PG2.

For example, the first group of pads PG1 comprises a first sub-group pads PG11 and a second sub-group pads PG12, wherein the first sub-group pads PG11 is located between the second sub-group pads PG12 and the second sub-group pads PG2. One or more pads of the second group of pads PG2 are connected to one or more pads of the first sub-group pads PG11 in one-to-one correspondence to input a signal to the integrated circuit. The second sub-group pads PG12 may output a signal from the integrated circuit. The first sub-group pads PG11 may also be referred to as signal input pads, and the second sub-group pads PG12 may also be referred to as signal output pads.

It is to be noted that, the second sub-group pads PG12 shown in FIG. 3 is only schematically shown to comprise one row of pads. In some embodiments, the second sub-group pads PG12 may comprise a plurality of rows of pads.

FIG. 1 also schematically shows a common voltage line COM, a data line DL, a gate line GL, a touch signal line Tx and a gate drive circuit GOA, which will be described later in conjunction with different embodiments. For example, the common voltage line COM is located at the peripheral area 12 and arranged around the display area 11.

Next, the structure of the array substrate located at the display area 11 will be described in conjunction with FIG. 2.

Referring to FIG. 2, a sub-pixel P comprises a pixel driving circuit comprising a transistor T, and the transistor T comprises a gate G, an active layer AT, a first electrode El and a second electrode E2. One of the first electrode El and the second electrode E2 is a source, and the other is a drain. It should be understood that, the pixel driving circuit also comprises other transistor(s) and a storage capacitor not shown in FIG. 2. It should also be understood that, the position of the gate G of the transistor T is only schematic. In some embodiments, the active layer AT is closer to the base substrate 10 than the gate G.

The pixel electrode PE is connected to the second electrode E2. For example, the pixel electrode PE is connected to the second electrode E2 through a via penetrating through the planarization layer 30. The material of the planarization layer 30 comprises, for example, an organic material such as polyimide (PI). The common electrode CE and the pixel electrode PE are spaced apart by an insulating layer 40. The material of the insulating layer 40 comprises, for example, an inorganic material such as silicon oxide, silicon nitride or silicon oxynitride.

In some embodiments, referring to FIG. 2, the pixel electrode PE is located on a surface of the planarization layer 30 away from the base substrate 10, and the common electrode CE is located on a surface of the insulating layer 40 away from the base substrate 10. In other embodiments, the pixel electrode PE is located on the surface of the insulating layer 40 away from the base substrate 10, and the common electrode CE is located on the surface of the planarization layer 30 away from the base substrate 10.

In some embodiments, the common electrode CE is multiplexed as a touch electrode TE. For example, the common electrode CE is located on the surface of the insulating layer 40 away from the base substrate 10. In this case, the common electrode CE is connected to the touch signal line Tx through a via penetrating through the insulating layer 40 and the planarization layer 30. For another example, the common electrode CE is located on the surface of the planarization layer 30 away from the base substrate 10. In this case, the common electrode CE is connected to the touch signal line Tx through a via penetrating through the planarization layer 30.

Next, the positional relationship between the signal line 20, the planarization layer 30 and the insulating layer 40 will be introduced in conjunction with FIG. 4. It may be understood that, the planarization layer 30 and the insulation layer 40 shown in FIG. 4 may extend from the display area 11 shown in FIG. 3 to the binding area C.

Referring to FIG. 4, the signal line 20 is located on one side of the base substrate 10, the planarization layer 30 is located on one side of the signal line 20 away from the base substrate 10, and the insulating layer 40 is located on one side of the planarization layer 30 away from the base substrate 10. In some embodiments, the signal line 20 comprises only a single metal layer. In other embodiments, the signal line 20 comprises a plurality of metal layers, for example, a first metal layer 21 and a second metal layer 22, and an insulating layer GI is provided between the first metal layer 21 and the second metal layer 22. As some implementations, the first metal layer 21 is located in a same layer as the gate G of the transistor T shown in FIG. 2, and the second metal layer 22 is located in a same layer as the first electrode El and the second electrode E2 of the transistor T shown in FIG. 2.

It is to be noted that, in the embodiments of the present disclosure, the expression that a plurality of components is located in a same layer means that the plurality of components is formed by patterning a same material layer. Therefore, the plurality of components in a same layer has a same material.

Referring to FIGS. 3 and 4, the planarization layer 30 has a groove R. It should be understood that, the groove R here penetrates through the planarization layer 30. The orthographic projection of the binding area C on the base substrate 10 is located within the orthographic projection of the groove R on the base substrate 10. In one or more implementations, the orthogonal projection of the signal line 20 on the base substrate 10 overlaps with the orthogonal projection of the groove R of the planarization layer 30 on the base substrate 10.

Next, different embodiments of the array substrate that can alleviate the problem of poor display will be described.

According to some embodiments of the present disclosure, the array substrate further comprises a plurality of connectors CM in addition to the base substrate 10, the first group of pads PG1, the second group of pads PG2, the signal line 20, the planarization layer 30, and the insulating layer 40 introduced above.

Next, the plurality of connectors CM will be described in conjunction with FIGS. 3 and 4.

Referring to FIG. 3, each connector CM among the plurality of connectors CM is connected to a corresponding pad in the first group of pads PG1 via a corresponding first connection line CL1/CL1′, is connected to a corresponding pad in the second group of pads PG2 via a corresponding second connection line CL2/CL2′.

In some embodiments, the plurality of connectors CM comprises a first connector CM1. For example, the first connector CM1 is configured to be applied a low-level voltage signal in at least one stage. For example, the first connector CM1 is connected to a corresponding first pad Pl in the first group of pads PG1 via a corresponding first connection line CL1, and the first connector CM1 is connected to a corresponding third pad P3 in the second group of pads PG2 via a corresponding second connection line CL2.

In other embodiments, the plurality of connectors CM further comprises a second connector CM2. For example, the second connector CM2 is configured to be applied a common voltage signal in at least one stage. The second connector CM2 is connected to a corresponding second pad P2 in the first group of pads PG1 via a corresponding first connection line CL1′, and the second connector CM2 is connected to a corresponding fourth pad P4 in the second group of pads PG2 via a corresponding second connection line CL2′.

Referring to FIG. 4, the plurality of connectors CM (for example, a first connector CM1 and a second connector CM2) is located on one side of the insulating layer 40 away from the base substrate 10.

Next, different implementations in a case where the array substrate comprises a plurality of connectors CM will be introduced.

As some implementations, referring FIG. 3, the orthographic projection of each connector CM among the plurality of connectors CM on the base substrate 10 overlaps with the orthographic projection of the signal line 20 on the base substrate 10, and does not overlap with the orthographic projection of the groove R of the planarization layer 30 on the base substrate 10. In this way, the insulating layer 40 and the planarization layer 30 present between each connector CM and the signal line 20. Compared to only the insulating layer 40 being present between a portion of the connector CM and the signal line 20, with the presence of both the insulating layer 40 and the planarization layer 30, it is less prone to ESD breakdown, and the signal line 20 is less prone to an electrochemical corrosion phenomenon, which is helpful to alleviate the problem of poor display.

As other implementations, referring to FIG. 3, the overlapping portion of the orthogonal projection of the signal line 20 on the base substrate 10 and the orthogonal projection of the groove R on the base substrate 10 does not overlap with the orthogonal projection signal line 20 of each connector CM on the base substrate 10. In this way, there is no connector CM immediately above the overlapping portion of the signal line 20 and the groove R of the planarization layer 30, and even if the insulating layer above the signal line 20 is broken down, a portion of the signal line 20 overlapped with the groove R is not prone to an electrochemical corrosion phenomenon, which is helpful to alleviate the problem of poor display.

As yet other implementations, referring to FIG. 3, the orthographic projection of each connector CM among the plurality of connectors CM on the base substrate 10 overlaps with the orthographic projection of the signal line 20 on the base substrate 10, and does not overlap with the orthographic projection of the groove R of the planarization layer 30 on the base substrate 10, and the orthographic projection of the signal line 20 on the base substrate 10 overlap with the orthographic projection of the groove R of the planarization layer 30 on the base substrate 10. In this way, in a case where the signal line 20 overlaps with the groove R, the problem of poor display can be alleviated without additionally changing the position of the signal line 20.

In some embodiments, at least one of the plurality of connectors CM shown in FIGS. 3 and 4 is located in a same layer as one or more components located at the display area 11. For example, at least one connector is located in a same layer as one of the pixel electrode PE and the common electrode CE shown in FIG. 2. In this way, it is helpful to simplify the manufacturing process of the array substrate. For example, the first connector M1 and the second connector M2 are both located in a same layer as the common electrode CE. For another example, in a case where the pixel electrode PE is closer to the base substrate 10 than the common electrode CE, the first connector M1 and the second connector M2 are both located in a same layer as the pixel electrode PE.

In some embodiments, the material of at least one of the plurality of connectors CM shown in FIGS. 3 and 4 comprises a transparent conductive material, such as indium tin oxide (ITO).

The inventors have noticed that, in some stage(s) (for example, during an on-going reliability test), a low-level voltage signal may be applied to the connector. In this case, there is a greater voltage difference between the connector and the signal line, and it is more prone to an electrochemical corrosion phenomenon, which results in that the signal line is more easily corroded.

In view showing this, the present disclosure also provides the following technical solutions.

According to other embodiments of the present disclosure, in addition to the base substrate 10, the first group of pads PG1, the second group of pads PG2, the signal line 20, the planarization layer 30, and the insulating layer 40 introduced above, the array substrate further comprises a first connector CM1 configured to be applied a low-level voltage signal in at least one stage. In some embodiments, at least one stage is a stage in an on-going reliability test.

Next, the connector CM1 will be introduced in conjunction with FIGS. 3 and 4.

Referring to FIG. 3, the first connector CM1 is connected to a corresponding pad (for example, the first pad P1) in the first group of pads PG1 via a corresponding first connection line CL1, and connected to a corresponding pad (for example, the third pad P3) in the second group of pads PG2 via a corresponding second connection line CL2.

Referring to FIG. 4, the first connector CM1 is located on one side of the insulating layer 40 away from the base substrate 10.

Next, different implementations in the case where the array substrate comprises the first connector CM1 will be introduced.

As some implementations, referring to FIG. 3, the orthographic projection of the first connector CM1 on the base substrate 10 overlaps with the orthographic projection of the signal line 20 on the base substrate 10, and does not overlap with the orthographic projection of the groove R on the base substrate 10. In this way, it is ensured that the insulating layer 40 and the planarization layer 30 are present between the first connector CM1 to which a low-level voltage signal is applied and the signal line 20, and the signal line 20 is less prone to an electrochemical corrosion phenomenon, which is helpful to effectively alleviate the problem of poor display.

As other implementations, referring to FIG. 3, the overlapping portion of the orthographic projections of the signal line 20 and the groove R on the base substrate 10 does not overlap with the orthographic projection of the first connector CM1 on the base substrate 10. In this way, the first connector CM1 to which a low-level voltage signal is applied is not present immediately above the overlapping portion of the signal line 20 and the groove R of the planarization layer 30, and even if the insulating layer 40 above the signal line 20 is broken down, the overlapping portion of the signal line 20 and the groove R is not prone to an electrochemical corrosion phenomenon, which is helpful to effectively alleviate the problem of poor display.

As yet other implementations, referring to FIG. 3, the orthographic projection of the first connector CM1 on the base substrate 10 overlaps with the orthographic projection of the signal line 20 on the base substrate 10, and does not overlap with the orthographic projection of the groove R on the base substrate 10. In this way, in the case where the signal line 20 overlaps with the groove R, the problem of poor display can be alleviated without additionally changing the position of the signal line 20.

In some embodiments, the array substrate further comprises a second connector CM2 in addition to the first connector CM1. The second connector CM2 is configured to be applied a common voltage signal at the above at least one stage. For example, in the case where a low-level voltage signal is applied to the first connector CM1, a common voltage signal is applied to the second connector CM2. As some implementations, in the above at least one stage, the voltage (for example, 0V voltage) of the signal applied to the second connector CM2 is greater than the voltage (for example, negative voltage) of the signal applied to the first connector CM1.

Next, some implementations of the second connector CM2 will be introduced in conjunction with FIGS. 3 and 4.

Referring to FIG. 3, the second connector CM2 is connected to a corresponding pad (for example, the second pad P2) in the first group of pads PG1 via a corresponding first connection line CL1′, and connected to a corresponding pad (for example, the fourth pad P4) in the second group of pads PG2 via a corresponding second connection line CL2′.

Referring to FIG. 4, the second connector CM2 is located on one side of the insulating layer 40 away from the base substrate 10.

As some implementations, referring to FIG. 3, the orthographic projection of the second connector CM2 on the base substrate 10 overlaps with the orthographic projection of the signal line 20 on the base substrate 10, and does not overlap with the orthographic projection of the groove R on the base substrate 10. In this way, the insulating layer 40 and the planarization layer 30 are present between the second connector CM2 to which a common voltage signal is applied and the signal line 20, and the signal line 20 is less prone to an electrochemical corrosion phenomenon, which is helpful to further alleviate the problem of poor display.

As other implementations, referring to FIG. 3, the overlapping portion of the orthographic projections of the signal line 20 and the groove R on the base substrate 10 does not overlap with the orthographic projection of the second connector CM2 on the base substrate 10. In this way, the second connector CM2 to which a common voltage signal is applied is not present immediately above the overlapping portion of the signal line 20 and the groove R of the planarization layer 30, and even if the insulating layer above the signal line 20 is broken down, the overlapping portion of the signal line 20 and the groove R is not prone to an electrochemical corrosion phenomenon, which is helpful to further display the bad problem.

In some embodiments, referring to FIG. 3, the orthographic projection of the first connector CM1 on the base substrate 10 is located between the orthographic projection of the second connector CM2 on the base substrate 10 and the binding area C.

Next, an array substrate according to still other embodiments of the present disclosure will be introduced.

In one or more embodiments, referring to FIG. 1, the array substrate further comprises a gate drive circuit GOA configured to provide a gate driving signal to a sub-pixel P located at the display area 11. In this case, the signal line 20 is configured to provide a signal to the gate drive circuit GOA. For example, the signal line 20 is connected to a certain pad in the first group of pads PG1 (for example, the first sub-group pads PG11). In the case where the technical solutions of various embodiments above are used, the signal line 20 is less prone to an electrochemical corrosion phenomenon, and thus it is helpful to alleviate the problem of poor display resulting from an abnormal signal provided to the gate drive circuit GOA.

In some embodiments, referring to FIG. 1, the gate drive circuit GOA is located at the peripheral area 12. As some implementations, the peripheral areas 12 on both opposite sides of the display area 11 may be provided with a gate drive circuit GOA respectively.

In one or more embodiments, referring to FIGS. 2 and 3, the array substrate further comprises a touch signal line Tx and a switch K. In some embodiments, the touch signal line Tx and the switch K are in one-to-one correspondence.

The touch signal line Tx is located at the display area 11. As some implementations, the touch signal line Tx is located in a same layer as the first electrode El and the second electrode E2 of the transistor T shown in FIG. 2. As other implementations, the touch signal line Tx comprises a plurality of metal layers, for example, a first metal layer 21 located in a same layer as the first electrode El and the second electrode E2 of the transistor T, and a second metal layer 22 located in a same layer as the gate G of the transistor T.

The gate G′ of the switch K is connected to the first connector CM1 via the first pad P1 in the first group of pads PG1, the first electrode El′ of the switch K is connected to the second connector CM2 via the second pad P2 in the first group of pads PG1, and the second electrode E2′ of the switch K is connected to the touch signal line Tx. The first electrode E1′ and the second electrode E2′ may comprise a single metal layer or double metal layers.

It is to be noted that, the position of the switch K shown in FIG. 3 is schematic. For example, the switch K may be located between the display area 11 and the first binding area C1.

In at least one stage, a low-level voltage signal is applied to the gate G′ of the switch K. For example, the switch K is an n-type transistor. In the case where a low-level voltage signal is applied to the gate G′, the switch K is turned off. In the case where a high-level voltage signal is applied to the gate G′, the switch K is turned on.

For example, in a first stage, a high-level voltage signal is applied to the gate G′ of the switch K, and the switch K is turned on to apply a touch signal to the touch signal line Tx, to perform a touch test. In a second stage, a low-level voltage signal is applied to the gate G′ of the switch K, and the switch K is turned off for other tests.

Since a low-level signal needs to be applied to the gate G′ of the switch K connected to the touch signal line Tx in a certain stage during the test, a low-level signal needs to be applied to the first connector CM1 connected to the gate G′ of the switch K. In this case, as previously analyzed, there is a greater voltage difference between the first connector CM1 and the signal line 20 and the signal line 20 is more easily corroded. By providing that the orthographic projections of the first connector CM1 and the groove R on the base substrate are not overlapped, or by providing that an Overlapping portion of the orthographic projections of the signal line 20 and the groove R on the base substrate does not overlap with the orthographic projection of the first connector CM1 on the base substrate, the risk of corrosion of the signal line 20 can be reduced, thereby effectively alleviating the problem of poor display.

Next, some embodiments of the array substrate will be further introduced in conjunction with FIGS. 5 to 7. In FIGS. 5 to 7, as some implementations, the first metal layer 21 is located in a same layer as the gate G of the transistor T shown in FIG. 2, and the second metal layer 22 is located in a same layer as the first electrode El and the second electrode E2 of the transistor T shown in FIG. 2.

FIG. 5 is a schematic cross-sectional view taken along B-B′ shown in FIG. 3.

In some embodiments, as shown in FIG. 5, the first connector CM1 may be connected to the first connection line CL1 through a first via V1 penetrating through the insulating layer 40, the planarization layer 30 and the insulating layer GI, and the first connector CM1 may be connected to the second connection line CL2 through a second via V2 penetrating through the insulating layer 40, the planarization layer 30 and the insulating layer GI. As some implementations, the first connection line CL1 and the second connection line CL2 each comprise the first metal layer 21, and the first connection line CL1′ and the second connection line CL2′ each comprise the first metal layer 21.

It is to be noted that, FIG. 5 only schematically shows the first connection line CL1′, but does not show the second connection line CL2′. For a positional relationship between the second connection line CL2′ and other layers, reference may be made to the positional relationship between the first connection line CL1′ and other layers.

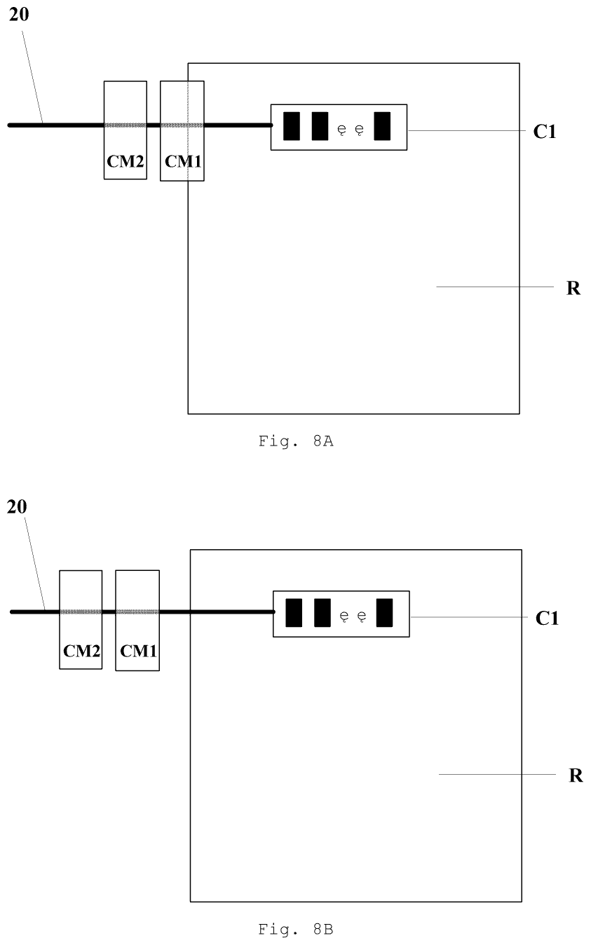

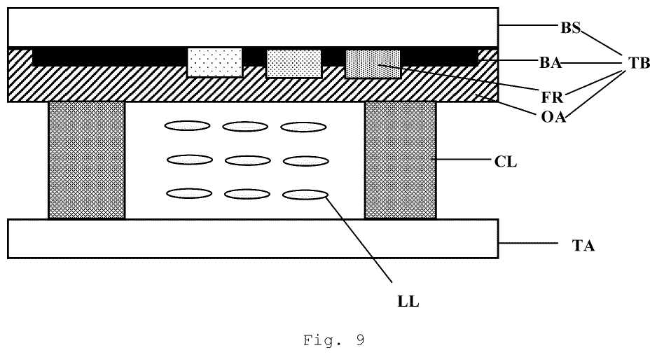

FIG. 6 is a schematic cross-sectional view taken along C-C′ shown in FIG. 3. FIG. 7 is a schematic cross-sectional view taken along D-D′ shown in FIG. 3.

In some embodiments, as shown in FIGS. 3, 6 and 7, each pad of the first group of pads PG1 is covered with a first connection electrode CM3, and each pad of the second group of pads PG1 is covered with a second connection electrode CM4, wherein the first connection electrode CM3 and the second connection electrode CM4 may protect the pads. In some embodiments, the first connection electrode CM3 and the second connection electrode CM4 are located in a same layer as the connector CM. In some embodiments, the first connection electrode CM3 and the second connection electrode CM4 are located in a same layer as one of the common electrode CE and the pixel electrode PE which is more away from the base substrate 10.

In some embodiments, as shown in FIG. 6, the first connection electrode CM3 is connected to a pad (for example, the first pad P1 or the second pad P2) in the first group of pads PG1 through a via.

FIG. 6 shows three connection methods which will be explained respectively below.

As some implementations, as shown in the leftmost view showing FIG. 6, the pad in the first group of pads PG1 comprises a first metal layer 21. In this case, the first connection electrode CM3 is connected to the first metal layer 21 as a pad through a via penetrating through the insulating layer 40 and the insulating layer GI.

As other implementations, as shown in the middle view showing FIG. 6, the pad in the first group of pads PG1 comprises a first metal layer 21 and a second metal layer 22. In this case, the first connection electrode CM3 is connected to the second metal layer 22 in the pad through a via penetrating through the insulating layer 40, and the first connection electrode CM3 is connected to the first metal layer 21 in the pad through a via penetrating through the insulating layer 40 and the insulating layer GI.

As yet other implementations, as shown in the rightmost view showing FIG. 6, the pad in the first group of pads PG1 comprises the second metal layer 22. In this case, the first connection electrode CM3 is connected to the second metal layer 22 as a pad through a via penetrating through the insulating layer 40.

In some embodiments, some pads in the first group of pads PG1 use a single metal layer (see the leftmost or rightmost view showing FIG. 6), while other pads use double metal layers (see the middle view showing FIG. 6). As some implementations, one pad of adjacent pads (for example, transversely adjacent pads) in the first group of pads PG1 uses a single metal layer, and the other pad uses double metal layers.

In some embodiments, as shown in FIG. 7, the second connection electrode CM4 is connected to a pad (for example, the third pad P3 or the fourth pad P4) in the second group of pads PG2 through a via.

Similar to FIG. 6, FIG. 7 also shows three connection methods which will be explained respectively below.

As some implementations, as shown in the leftmost view showing FIG. 7, the pad in the second group of pads PG2 comprises a first metal layer 21. In this case, the second connection electrode CM4 is connected to the first metal layer 21 as a pad through a via penetrating through the insulating layer 40 and the insulating layer GI.

As other implementations, as shown in the middle view showing FIG. 7, the pad in the second group of pads PG2 comprises a first metal layer 21 and a second metal layer 22. In this case, the second connection electrode CM4 is connected to the second metal layer 22 in the pad through a via penetrating through the insulating layer 40, and the second connection electrode CM4 is connected to the first metal layer 21 in the pad through a via penetrating through the insulating layer 40 and the insulating layer GI.

As yet other implementations, as shown in the rightmost view showing FIG. 7, the pad in the second group of pads PG2 comprises a second metal layer 22. In this case, the second connection electrode CM4 is connected to the second metal layer 22 as a pad through a via penetrating through the insulating layer 40.

In some embodiments, some pads in the second group of pads PG2 use a single metal layer (see the leftmost or rightmost view showing FIG. 7), while other pads use double metal layers (see the middle view showing FIG. 7). As some implementations, one pad of adjacent pads (for example, transversely adjacent pads) in the second group of pads PG2 uses a single metal layer, and the other pad uses double metal layers.

The first group of pads PG1 may be connected to the second group of pads PG2 via a third connection line CL3 and a fourth connection line CL4 respectively. For example, one pad in the first group of pads PG1 is connected to one pad in the second group of pads PG2 via the third connection line CL3; and another pad in the first group of pads PG1 is connected to another pad in the second group of pads PG2 via the fourth connection line CL4. As some implementations, the third connection line CL3 comprises the first metal layer 21, and the fourth connection line CL4 comprises the first metal layer 21 and the second metal layer 22.

In order to highlight some components, each of FIGS. 4 to 7 schematically shows a plurality of spaced apart parts. For example, FIGS. 4 and 5 show four parts, FIG. 6 shows three parts and FIG. 7 shows two parts. It is to be noted that, the layers marked by the same reference numeral in different parts of each figure are continuous.

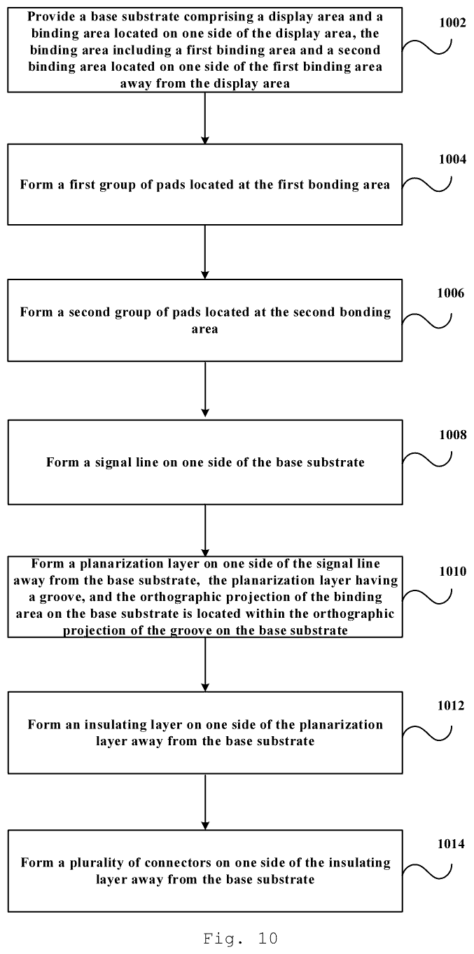

FIG. 8A is a partial schematic view showing an array substrate in the related art. FIG. 8B is a partial schematic view showing an array substrate according to some embodiments of the present disclosure.

As shown in FIG. 8A, in the related art, the first connector CM1 is crossed at the boundary of the groove R, which results in the problem that the signal line 20 is easily corroded and leads to poor display.

As shown in FIG. 8B, in some embodiments of the present disclosure, the first connector CM1 is not crossed at the boundary of the groove R, and the signal line 20 is not easily corroded, thereby improving the problem of poor display.

FIG. 9 is a schematic structural view showing a display panel according to some embodiments of the present disclosure.

As shown in FIG. 9, the display panel comprises an array substrate TA, a color filter substrate TB, and a liquid crystal layer LL located between the array substrate TA and the color filter substrate TB. The array substrate TA may be the array substrate according to any of the above embodiments. It is to be noted that, FIG. 9 only schematically shows a base substrate BS, a black matrix BA, an optical filter FR and an optical adhesive OA in the color filter substrate TB. It may be understood that, the color filter substrate TB may also comprise other components, such as a polarizer.

In some embodiments, the array substrate TA and the color filter substrate TB may be joined by a frame sealing adhesive CL.

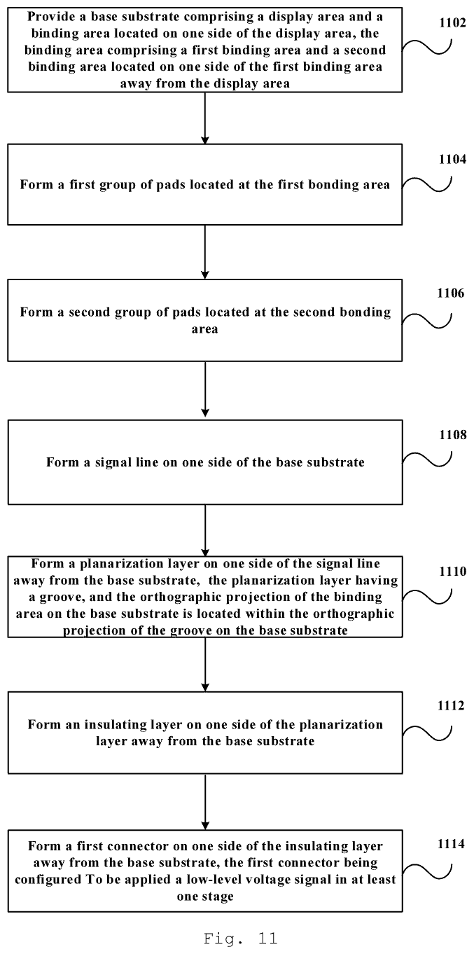

FIG. 10 is a flowchart showing a manufacturing method of an array substrate according to some embodiments of the present disclosure.

At step 1002, a base substrate is provided. The base substrate comprises a display area and a binding area located on one side of the display area, and the binding area comprises a first binding area and a second binding area located on one side of the first binding area away from the display area.

At step 1004, a first group of pads located at the first bonding area is formed.

At step 1006, a second group of pads located at the second bonding area is formed.

At step 1008, a signal line is formed on one side of the base substrate.

At step 1010, a planarization layer is formed on one side of the signal line away from the base substrate. The planarization layer has a groove, and the orthographic projection of the binding area on the base substrate is located within the orthographic projection of the groove on the base substrate.

At step 1012, an insulating layer is formed on one side of the planarization layer away from the base substrate.

At step 1014, a plurality of connectors is formed on one side of the insulating layer away from the base substrate. Each of the plurality of connectors is connected to a corresponding pad in the first group of pads via a corresponding first connection line respectively, and connected to a corresponding pad in the second group of pads via a corresponding second connection line respectively.

In some embodiments, the orthographic projection of each of the plurality of connectors on the base substrate overlaps with the orthographic projection of the signal line on the base substrate, and does not overlap with the orthographic projection of the groove on the base substrate. In this way, the insulating layer and the planarization layer are present between each connector and the signal line. Compared to only the insulating layer being present between a portion of the connector and the signal line, with the presence of both the insulating layer and the planarization layer, it is less prone to ESD breakdown, and the signal line is less prone to an electrochemical corrosion phenomenon, which is helpful to alleviate the problem of poor display.

In other embodiments, an overlapping portion of the orthogonal projections of the signal line and the groove on the base substrate does not overlap with the orthogonal projection of each of the plurality of connectors on the base substrate. In this way, the connector is not present immediately above the overlapping portion of the signal line and the groove of the planarization layer, and even if the insulating layer above the signal line is broken down, the overlapping portion of the signal line and the groove is not prone to an electrochemical corrosion phenomenon, which is helpful to alleviate the problem of poor display.

FIG. 11 is a flowchart showing a manufacturing method of an array substrate according to other embodiments of the present disclosure.

At step 1102, a base substrate is provided. The base substrate comprises a display area and a binding area located on one side of the display area. The binding area comprises a first binding area and a second binding area located on one side of the first binding area away from the display area.

At step 1104, a first group of pads located at the first bonding area is formed.

At step 1106, a second group of pads located at the second bonding area is formed.

At step 1108, a signal line is formed on one side of the base substrate.

At step 1110, a planarization layer is formed on one side of the signal line away from the base substrate. The planarization layer has a groove, and the orthographic projection of the binding area on the base substrate is located within the orthographic projection of the groove on the base substrate.

At step 1112, an insulating layer is formed on one side of the planarization layer away from the base substrate.

At step 1114, a first connector is formed on one side of the insulating layer away from the base substrate. The first connector is configured to be applied a low-level voltage signal in at least one stage, and the first connector is connected to a corresponding pad in the first group of pads via a corresponding first connection line, and connected to a corresponding pad in the second group of pads via a corresponding second connection line.

In some embodiments, the orthographic projection of the first connector on the base substrate overlaps with the orthographic projection of the signal line on the base substrate, and does not overlap with the orthographic projection of the groove on the base substrate. In this way, it is ensured that there is an insulating layer and a planarization layer between the first connector to which a low-level voltage signal is applied and the signal line, and the signal line is less prone to an electrochemical corrosion phenomenon, which is helpful to effectively alleviate the problem of poor display.

In other embodiments, the overlapping portion of the orthographic projections of the signal line and the groove on the base substrate does not overlap with the orthographic projection of the first connector on the base substrate. In this way, the first connector to which a low-level voltage signal is applied is not present immediately above the overlapping portion of the signal line and the groove of the planarization layer, and even if the insulating layer above the signal line is broken down, the overlapping portion of the signal line and the groove is not prone to an electrochemical corrosion phenomenon, which is helpful to effectively alleviate the problem of poor display.

It is to be noted that, the steps shown in FIGS. 10 and 11 are not necessarily performed according to the sequence of the steps as shown. In some embodiments, some steps may be performed in parallel. For example, a plurality of steps in steps 1004, 1006 and 1008 may be performed in parallel, and a plurality of steps in steps 1104, 1106 and 1108 may be performed in parallel.

The present disclosure also provides a display device, which may comprise the array substrate according to any of the above embodiments. In some embodiments, the display device may be, for example, any product or member having a display function, such as a mobile terminal, a television, a display, a notebook computer, a tablet computer, a digital photo frame, a navigator, or an electronic paper.

In some embodiments, the display device is a TDDI display device.

Hereto, various embodiments of the present disclosure have been described in detail. Some details well known in the art are not described to avoid obscuring the concept of the present disclosure. According to the above description, those skilled in the art would fully know how to implement the technical solutions disclosed herein.

Although some specific embodiments of the present disclosure have been described in detail by way of examples, those skilled in the art should understand that the above examples are only for the purpose of illustration and are not intended to limit the scope of the present disclosure. It should be understood by those skilled in the art that modifications to the above embodiments and equivalently substitution of part of the technical features can be made without departing from the scope and spirit of the present disclosure. The scope of the disclosure is defined by the following claims.

1. An array substrate, comprising:
a base substrate comprising a display area and a binding area located on one side of the display area, wherein the binding area comprises a first binding area and a second binding area located on one side of the first binding area away from the display area;
a first group of pads located at the first binding area;
a second group of pads located at the second binding area;
a signal line located on one side of the base substrate;
a planarization layer located on one side of the signal line away from the base substrate, wherein the planarization layer has a groove, and an orthographic projection of the binding area on the base substrate is located within an orthographic projection of the groove on the base substrate;
an insulating layer located on one side of the planarization layer away from the base substrate; and
a plurality of connectors located on one side of the insulating layer away from the base substrate, wherein each of the plurality of connectors is connected to a corresponding pad in the first group of pads via a corresponding first connection line respectively, and connected to a corresponding pad in the second group of pads via a corresponding second connection line respectively,
wherein an orthographic projection of each of the plurality of connectors on the base substrate overlaps with an orthographic projection of the signal line on the base substrate, and does not overlap with the orthographic projection of the groove on the base substrate.

2. The array substrate according to claim 1, wherein the orthogonal projection of the signal line on the base substrate overlaps with the orthogonal projection of the groove on the base substrate.

3. An array substrate, comprising:
a base substrate comprising a display area and a binding area located on one side of the display area, wherein the binding area comprises a first binding area and a second binding area located on one side of the first binding area away from the display area;
a first group of pads located at the first binding area;
a second group of pads located at the second binding area;
a signal line located on one side of the base substrate;
a planarization layer located on one side of the signal line away from the base substrate, wherein the planarization layer has a groove, and an orthographic projection of the binding area on the base substrate is located within an orthographic projection of the groove on the base substrate;
an insulating layer located on one side of the planarization layer away from the base substrate; and
a plurality of connectors located on one side of the insulating layer away from the base substrate, wherein each of the plurality of connectors is connected to a corresponding pad in the first group of pads via a corresponding first connection line respectively, and connected to a corresponding pad in the second group of pads via a corresponding second connection line respectively,
wherein an overlapping portion of orthogonal projections of the signal line and the groove on the base substrate does not overlap with an orthogonal projection of each of the plurality of connectors on the base substrate.

4. The array substrate according to claim 1, wherein the plurality of connectors comprises a first connector configured to be applied a low-level voltage signal in at least one stage.

5. The array substrate according to claim 4, wherein the plurality of connectors further comprises a second connector configured to be applied a common voltage signal in the at least one stage.

6. An array substrate, comprising:
a base substrate comprising a display area and a binding area located on one side of the display area, wherein the binding area comprises a first binding area and a second binding area located on one side of the first binding area away from the display area;
a first group of pads located at the first binding area;
a second group of pads located at the second binding area;
a signal line located on one side of the base substrate;
a planarization layer located on one side of the signal line away from the base substrate, wherein the planarization layer has a groove, and an orthographic projection of the binding area on the base substrate is located within an orthographic projection of the groove on the base substrate;
an insulating layer located on one side of the planarization layer away from the base substrate; and
a first connector located on one side of the insulating layer away from the base substrate and configured to be applied a low-level voltage signal in at least one stage, wherein the first connector is connected to a corresponding pad in the first group of pads via a corresponding first connection line, and connected to a corresponding pad in the second group of pads via a corresponding second connection line,
wherein an orthographic projection of the first connector on the base substrate overlaps with an orthographic projection of the signal line on the base substrate, and does not overlap with the orthographic projection of the groove on the base substrate.

7. The array substrate according to claim 6, wherein the orthogonal projection of the signal line on the base substrate overlaps with the orthogonal projection of the groove on the base substrate.

8. The array substrate according to claim 7,
wherein an overlapping portion of orthographic projections of the signal line and the groove on the base substrate does not overlap with an orthographic projection of the first connector on the base substrate.

9. The array substrate according to claim 6, further comprising:
a second connector located on one side of the insulating layer away from the base substrate and configured to be applied a common voltage signal in the at least one stage, wherein the second connector is connected to a corresponding pad in the first group of pads via a corresponding first connection line, and connected to a corresponding pad in the second group of pads via a corresponding second connection line,
wherein an orthographic projection of the second connector on the base substrate overlaps with the orthographic projection of the signal line on the base substrate, and does not overlap with the orthographic projection of the groove on the base substrate.

10. The array substrate according to claim 6, further comprising:
a second connector located on one side of the insulating layer away from the base substrate and configured to be applied a common voltage signal in the at least one stage, wherein the second connector is connected to a corresponding pad in the first group of pads via a corresponding first connection line, and connected to a corresponding pad in the second group of pads via a corresponding second connection line,
wherein an overlapping portion of orthographic projections of the signal line and the groove on the base substrate does not overlap with an orthographic projection of the second connector on the base substrate.

11. The array substrate according to claim 5, further comprising:
a touch signal line located at the display area; and
a switch, wherein a gate of the switch is connected to the first connector via a first pad in the first group of pads, a first electrode of the switch is connected to the second connector via a second pad in the first group of pads, and a second electrode of the switch is connected to the touch signal line.

12. The array substrate according to claim5, wherein an orthographic projection of the first connector on the base substrate is located between an orthographic projection of the second connector on the base substrate and the binding area.

13. The array substrate according to claim 4, wherein the at least one stage is a stage during an on-going reliability test.

14. The array substrate according to claim 1, further comprising:
a gate drive circuit configured to provide a gate driving signal to a sub-pixel located at the display area,
wherein the signal line is configured to provide a signal to the gate drive circuit.

15. The array substrate according to claim 1, further comprising:
a touch electrode multiplexed as a common electrode.

16. The array substrate according to claim 1, wherein:
the first binding area is an integrated circuit binding area; and
the second binding area is a circuit board binding area.

17. The array substrate according to claim 1, wherein at least one connector is located in a same layer as one of a pixel electrode and a common electrode in the array substrate.

18. The array substrate according to claim 1, wherein a material of at least one connector comprises a transparent conductive oxide.

19. A display panel comprising:
the array substrate according to claim 1;
a color filter substrate; and
a liquid crystal layer located between the array substrate and the color filter substrate.

20. A display device, comprising the display panel according to claim 19.
